(19) United States
(12) Patent Application Publication
(10) Pub. No.: US 2004/0266054 A1
(43) Pub. Date: Dec. 30, 2004

(54) OFET channel fabrication

(76) Inventors: Paul W. Brazis, South Elgin, IL (US); Daniel R. Gamota, Palatine, IL (US); Krishna Kalyanasundaram, Chicago, IL (US); Jie Zhang, Buffalo Grove, IL (US)

Correspondence Address: DANIEL K. NICHOLS, Motorola, Inc., Law Department, 1303 E. Algonquin Road, Schaumburg, IL, 60196, US

(21) Appl. No.: 10/609,860

(22) Filed: Jun. 30, 2003

(51) Int. Cl. H01L 51/40; H01L 21/44

(52) U.S. Cl. 438/99; 438/708; 438/660

(57) ABSTRACT

An exemplary system and method for defining fine printed OFET features is disclosed as comprising inter alia: printed deposition of a conductive material on a substrate; and laser-assisted ablative removal of at least a portion of the conductive material to define source and drain electrode structures. Disclosed features and specifications may be variously controlled, adapted or otherwise optionally modified to improve OFET feature definition. Exemplary embodiments of the present invention representatively provide for resolved OFET channel features that may be readily integrated with or extended to other organic electronic technologies for the improvement of device package form factors, weights and other manufacturing and/or device performance metrics.

### FIELD OF INVENTION

The present invention generally concerns semiconductors; and more particularly, in various representative and exemplary embodiments, to methods of fabricating organic semiconductor channel structures.

### BACKGROUND

Metal-insulator-semiconductor and metal Schottky field effect transistors (MISFETs and MESFETs, respectively) and other circuits comprised of semiconductor materials are generally known in the art and have been relatively successfull; however, for some applications, traditional semiconductor processes and/or materials may tend to over-perform and present unneeded form factors or other capabilities at disproportionate cost. For example, conventional semiconductor processing often yields small parts that tend to produce handling difficulties during assembly, generally requiring careful packaging, and typically employ batch processing to achieve reasonable cost per unit part since inter alia the fabrication facilities and equipment can be relatively expensive. Also, many semiconductor devices generally require lengthy fabrication times and numerous chemicals, which may be toxic or otherwise require special handling. Accordingly, representative aspects of conventional semiconductor fabrication may not be suitably adapted to support high surface area, low data storage, low transmission rate and/or various other cost- or performance- constrained product applications.

Conventional techniques for defining features during organic field effect transistor (OFET) fabrication has typically involved the use of photolithography and vacuum deposition. For the definition of finely-printed OFET features, resolution has been typically limited by what has been generally achievable with existing printing technologies. Somewhat newer techniques, such as for example, micro-contact printing (μ-CP) have demonstrated substantially smaller feature sizes; however, μ-CP has not been shown to be compatible with large-scale production due to inter alia the fragile stamps used, alignment issues, poor throughput, etc. Another approach has involved pre-patterning the substrate before printing where a photomask may be used to define a hydrophobic region within a channel with surrounding hydrophilic regions. The modified wetting properties of the substrate generally afford a narrower feature size after printing than would otherwise be achievable without the use of such feature-enhancing techniques. While this method has been demonstrated in certain laboratory settings, it is uncertain whether the process can be made cost effective for mass production. Notwithstanding the preceding, a method of forming sufficiently narrow channels that is compatible with existing manufacturing processes is desirable for improved or otherwise suitable OFET performance.

### SUMMARY OF THE INVENTION

In various representative aspects, the present invention provides a system and method for defining fine printed OFET features. An exemplary system and method for providing such a device is disclosed as comprising inter alia: deposition of a conductive material on a substrate; and ablative removal of at least a portion of the conductive material to define source and drain electrode structures. Fabrication is relatively simple and straightforward. Additional advantages of the present invention will be set forth in the Detailed Description which follows and may be obvious from the Detailed Description or may be learned by practice of exemplary embodiments of the invention. Still other advantages of the invention may be realized by means of any of the instrumentalities, methods or combinations particularly pointed out in the claims.

### BRIEF DESCRIPTION OF THE DRAWING

Representative elements, operational features, applications and/or advantages of the present invention reside inter alia in the details of construction and operation as more fully hereafter depicted, described and claimed—reference being made to the accompanying drawing forming a part hereof, wherein like numerals refer to like parts throughout. Other elements, operational features, applications and/or advantages will become apparent to skilled artisans in light of certain exemplary embodiments recited in the Detailed Description, wherein:

FIG. 1 representatively depicts a cross-sectional side elevation view of starting, intermediate and resulting device structures in accordance with an exemplary embodiment of the present invention.

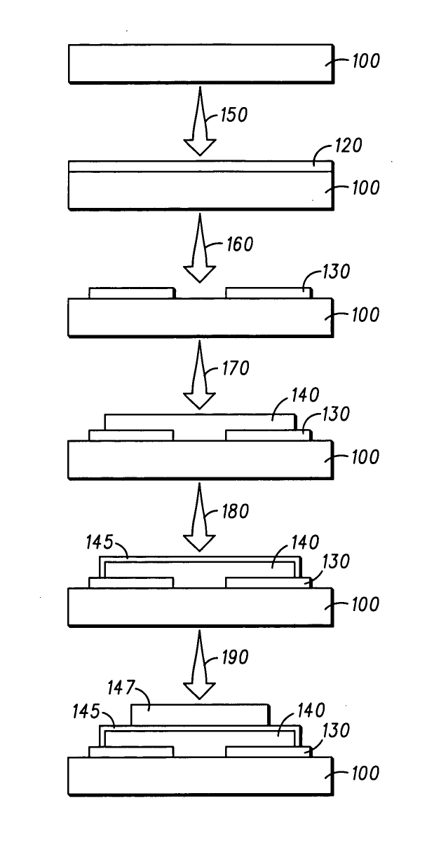

Those skilled in the art will appreciate that elements in the FIGURE are illustrated for simplicity and clarity and have not necessarily been drawn to scale. For example, the dimensions of some of the elements in the FIGURE may be exaggerated relative to other elements to help improve understanding of various embodiments of the present invention. Furthermore, the terms ‘first’, ‘second’, and the like herein, if any, are used inter alia for distinguishing between similar elements and not necessarily for describing a sequential or chronological order. Moreover, the terms front, back, top, bottom, over, under, and the like in the Description and/or in the claims, if any, are generally employed for descriptive purposes and not necessarily for comprehensively describing exclusive relative position. Skilled artisans will therefore understand that any of the preceding terms so used may be interchanged under appropriate circumstances such that various embodiments of the invention described herein, for example, are capable of operation in other geometries, configurations and/or orientations than those explicitly illustrated or otherwise described.

### DETAILED DESCRIPTION OF EXEMPLARY EMBODIMENTS

The following descriptions are of exemplary embodiments of the invention and the inventors' conceptions of the best mode and are not intended to limit the scope, applicability or configuration of the invention in any way. Rather, the following Description is intended to provide convenient illustrations for implementing various embodiments of the invention. As will become apparent, changes may be made in the function and/or arrangement of any of the elements described in the disclosed exemplary embodiments without departing from the spirit and scope of the invention.

A detailed description of an exemplary application, namely a system and method for cutting narrow OFET channels using laser ablation is provided as a specific enabling disclosure that may be readily generalized by skilled artisans to any application of the disclosed system and method for defining electronic features in accordance with various other embodiments of the present invention.

Fabrication of organic electronics with printing technologies promises cost-effective circuitry for use in conjunction with, for example, consumer products. The level of performance achieved by constituent active devices fabricated via printing generally depends inter alia on the achievable printed feature size. An important attribute of a printed OFET is the channel length, where a minimal spacing between the source and drain electrode is typically desired. A narrower channel length generally provides improved current carrying capability and enhanced operating speed typically without the need for modifying the composition of the organic semiconductor. This approach for realizing improved performance is analogous to what has been conventionally used to improve silicon-based device operation for some time.

The width of the cut, described in accordance with various exemplary embodiments of the present invention, generally defines the channel length L. Accordingly, the current across the channel may be given by the following equation:

$${I}_{D} = \frac{W}{L} μ {C}_{i} [ {( {V}_{G} - {V}_{T} )}^{2} - \frac{{V}_{D}^{2}}{2} ] ,$$

where I_{D} represents the current passed through the channel (drain to source); W the channel width; μ the carrier mobility through the semiconductor; Cᵢ the capacitance per unit area of gate dielectric; V_{G} the voltage at gate (referenced to source); V_{T} the threshold voltage; and V_{D} the voltage at drain (referenced to source).

As expressed vide supra, the drain current I_{D} is inversely proportional to the channel length. Therefore, as the channel is narrowed the amount of current through the drain is increased (assuming constant channel width W, mobility μ, capacitance Cᵢ, and gate and drain voltages V_{G} and V_{D}). Reduced channel length also contributes to proportionately increased operating speed inasmuch as the charge carriers have a shorter distance to travel between the source and drain electrodes.

In accordance with an exemplary and representative embodiment of the present invention, a method for obtaining a narrow channel length with laser cutting is disclosed. As generally depicted, for example, in the attached FIGURE, this may be achieved by printing/depositing (step 150) a conductive region 120 on a substrate 100 then forming the channel by using a laser (step 160) to remove the conductive material 120 forming at least a discontinuity between separated conductive regions 130. The printing/deposition technologies used for conductor fabrication need not be restricted by high precision or resolution specification; hence, any and all printing/deposition techniques currently known, hereafter discovered or otherwise described in the art may be adopted.

It may be desirable that the substrate not be damaged or otherwise altered during the laser cutting process. This may be achieved, for example, by: appropriately selecting the substrate material so that energy from the laser is generally not substantially absorbed; or selecting a wavelength so that energy is preferentially absorbed by the conductive material with respect to the substrate. Any method of directing or otherwise optimizing the deposition of laser energy, such as for example, in the PWB board fabrication and resistor trimming art, whether now known, hereafter discovered or otherwise described may be alternatively, conjunctively or sequentially used.

A transistor structure may be fabricated using printing technology on a low-cost substrate, such as plastic or paper. One method of fabrication begins with a single region of conductive material 120 deposited (step 150) on a substrate 100 (deposition may include print/etch, or various contact or contact-free printing methods). The source and drain electrodes 130 may then be formed (step 160) by bisecting (e.g., linearly or nonlinearly) the conductive region 120 with a laser, forming a channel between the electrodes 130. An organic semiconductor 140 may be deposited (step 170) on top of the electrode structure 130, then a dielectric 145 (step 180) and gate electrode 147 (step 190).

The transistor structure may also be fabricated using, for example, two low-cost substrates, with the source and drain fabricated in a similar manner to that in the previously embodiment vide supra. On a second substrate, a gate electrode may be deposited. A dielectric may then be deposited (for example, by printing or by oxidation of the gate metal) substantially covering the gate electrode. An organic semiconducting material may then be placed over the dielectric. The two substrates may then be laminated together so that the source and drain are placed in effective contact with the semiconductor layer.

Various representative embodiments of the present invention have been demonstrated using laser cutting and trimming equipment that is commercially available from Lasag Industrial Lasers (Arlington Heights, Ill., USA). In proof-of-concept trials, channels on the order of less than about 25-μm were defined using a excimer laser. Ablations were successful in electrically isolating the patterned copper source and drain regions and formed a useable channel. Systems exist that can achieve sub-1 μm features from commercial laser suppliers known to those skilled in the art. These suppliers produce equipment which offer shorter wavelengths capable of cutting narrower channels on the order of those described in accordance with the present invention.

In the foregoing specification, the invention has been described with reference to specific exemplary embodiments; however, it will be appreciated that various modifications and changes may be made without departing from the scope of the present invention as set forth in the claims below. The specification and FIGURE are to be regarded in an illustrative manner, rather than a restrictive one and all such modifications are intended to be included within the scope of the present invention. Accordingly, the scope of the invention should be determined by the claims appended hereto and their legal equivalents rather than by merely the examples described above. For example, the steps recited in any method or process claims may be executed in any order and are not limited to the specific order presented in the claims.

Additionally, the components and/or elements recited in any apparatus claims may be assembled or otherwise operationally configured in a variety of permutations to produce substantially the same result as the present invention and are accordingly not limited to the specific configuration recited in the claims.

Benefits, other advantages and solutions to problems have been described above with regard to particular embodiments; however, any benefit, advantage, solution to problems or any element that may cause any particular benefit, advantage or solution to occur or to become more pronounced are not to be construed as critical, required or essential features or components of any or all the claims.

As used herein, the terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted by those skilled in the art to specific environments, manufacturing specifications, design parameters or other operating requirements without departing from the general principles of the same.

We claim:

1. A method for defining OFET features, said method comprising the steps of:
providing a substrate;
depositing an at least partially conductive material on said substrate; and
using a laser to ablatively remove at least a portion of said conductive material.

2. The method of claim 1, wherein said substrate comprises material selected so as not to substantially absorb energy from said laser.

3. The method of claim 1, wherein said conductive material comprises material selected so as to preferentially absorb energy from said laser with respect to the substrate material.

4. The method of claim 1, wherein said substrate comprises at least one of a polymer material, a polymer composite material and polyester.

5. The method of claim 1, wherein said deposition of said conductive material comprises at least one of contact printing, micro-contact printing and contact-free printing.

6. The method of claim 5, further comprising the step of bisecting said conductive material to form a channel between a source and a drain electrode.

7. The method of claim 6, wherein said step of bisecting further comprising at least one of linear bisection and non-linear bisection.

8. The method of claim 6, further comprising the step of depositing an organic semiconductor material over said electrodes.

9. The method of claim 8, further comprising the step of depositing a dielectric material over said organic semiconductor material.

10. The method of claim 9, further comprising the step of depositing a gate electrode structure over said dielectric material.

11. A method for defining OFET features, said method comprising the steps of:
providing a first substrate;
providing a second substrate;
depositing an at least partially conductive material on said first substrate;
depositing a gate electrode structure on said second substrate;
depositing a dielectric material over said gate electrode structure;
depositing a layer of organic semiconducting material over said dielectric material;
using a laser to ablatively remove at least a portion of said conductive material so as to form a channel between a source electrode and a drain electrode; and
laminating said first substrate together with said second substrate such that said source and drain electrodes are placed in effective contact said semiconducting layer.

12. The method of claim 11, wherein said first substrate comprises material selected so as not to substantially absorb energy from said laser.

13. The method of claim 11, wherein said conductive material comprises material selected so as to preferentially absorb energy from said laser with respect to the first substrate material.

14. The method of claim 11, wherein said first substrate comprises at least one of a polymer material, a polymer composite material and polyester.

15. The method of claim 11, wherein said deposition of said conductive material comprises at least one of contact printing, micro-contact printing and contact-free printing.

16. The method of claim 11, wherein said step of ablative removal of said conductive material comprises at least one of linear bisection and non-linear bisection.

17. An OFET device, said device manufactured in accordance with the method of claim 1.

18. An OFET device, said device manufactured in accordance with the method of claim 6.

19. An OFET device, said device manufactured in accordance with the method of claim 10.

20. An OFET device, said device manufactured in accordance with the method of claim 15.
